(19) United States
(12) Patent Application Publication
(10) Pub. No.: US 2016/0289401 A1
(43) Pub. Date: Oct. 6, 2016

(54) ARTICLE INCLUDING POLYMER HAVING SURFACE WITH LOW COEFFICIENT OF FRICTION AND MANUFACTURING METHOD OF SUCH

(71) Applicant: 3M INNOVATIIVE PROPERTIES COMPANY, Saint Paul, MN (US)

(72) Inventors: Naota Sugiyama, Tokyo (JP); Hideki Minami, Tokyo (JP); Yoshihisa Matsuda, Kanagawa (JP); Satoshi Akutagawa, Tokyo (JP); Tetsuya Noro, Yokohama (JP)

(21) Appl. No.: 14/777,832

(22) PCT Filed: Mar. 14, 2014
(86) PCT No.: PCT/US14/27286

§ 371 Date: Sep. 17, 2015

(30) Foreign Application Priority Data
Mar. 25, 2013 (JP) 2013-062559

(51) Int. Cl. C08J 3/28; C08G 77/04; C08F 214/22; H01J 37/32; C08F 214/28

(52) U.S. Cl. CPC C08J 3/28; H01J 37/3244; C08F 214/28; C08F 214/22; C08G 77/04; H01J 2237/336

(57) ABSTRACT

An article is provided that includes a polymer having a surface that has excellent heat resistance, weathering resistance, or the like and has a low coefficient of friction. Additionally, a method of manufacturing the article is provided. The article includes a polymer having a surface that has been plasma treated in flowing gas including at least one type of silicon-containing gas selected from the group consisting of tetramethylsilane, hexamethyldisiloxane, and hexamethyldisilazane. The polymer is selected from the group consisting of silicones and fluorocarbon polymers.

### CROSS REFERENCE TO RELATED APPLICATION

This application claims priority to Japanese Patent Application JP2013-062559, filed on Mar. 25, 2013, the disclosure of which is incorporated by reference in its entirety.

1. Field of the Invention

The present disclosure relates to an article including a polymer having a surface that has excellent heat resistance, weathering resistance, or the like and that has a low coefficient of friction, and a manufacturing method of such an article.

2. Background

In recent years, light emitting diodes (LEDs) and related products have been used in various types of applications instead of conventional light sources. One such application has been an advertising display utilizing light emitting diodes. In part of the advertising display, a transmissive diffuser panel for increasing visual recognition is attached to the outermost surface of the advertising display.

As an example of a material used in a transmissive diffuser panel, Patent Document 1 (Japanese Unexamined Patent Application Publication No. 2007-112935) mentions “a light diffusing resin composition including from 99 to 99.999 weight % of a cyclic olefin resin (A), from 0.001 to 1 weight % of hollow particles (B) (where (A)+(B)=100 weight %); the absolute value |nB−nA| of the difference between the refractive index nA of the aforementioned cyclic olefin resin (A) and the refractive index nB of the aforementioned hollow particles (B) being greater than or equal to 0.04, and the average particle diameter of the aforementioned hollow particles (B) being greater than or equal to 2.0 micrometers (μm).

By use of a silicone resin as the matrix of a transmissive diffuser panel that has properties such as heat resistance, weathering resistance, water repellency, or the like, it is thought to be possible to manufacture a transmissive diffuser panel that is resistant to the heat generated by LEDs and that is particularly suitable for outdoor applications. However, since the surface of silicone resin does not have a sufficiently low coefficient of friction, dust may attach to the surface or the removal of dirt may be difficult.

A polymer insulator is cited as an application of outdoor use in the same manner as a transmissive diffuser panel. A polymer insulator is configured from an FRP core, metal fittings attached to both edges thereof, and an umbrella-shaped jacketing material for covering the outer periphery of the FRP core. Silicone rubber, which has excellent insulation ability, heat resistance, weathering resistance, or the like, is mainly used as the jacketing material.

For example, Patent Document 2 (Japanese Unexamined Patent Application Publication No. 2007-180044) mentions “a method for improving high voltage electrical insulation characteristics of a polymer insulator molded in an insulator or bushing shape by coating a silicone rubber composition on the outer periphery of a core formed from thermoplastic resin and then curing the assembly; the method using as the aforementioned silicone rubber composition a silicone rubber composition for use in high voltage electrical insulator including: (a) 100 parts by weight of an organic peroxide curing-type or addition curing-type organo-polysiloxane composition; (b) from 1 to 100 parts by weight of silica fine powder; and (c) from 30 to 500 parts by weight of aluminum hydroxide having less than or equal to 0.01 weight % of water soluble Na ions, where a pH value is greater than or equal to 6.5 and less than or equal to 8.0 for a 30 weight % aqueous slurry, and an electrical conductivity is less than or equal to 50 μs/cm.”

Silicone rubber is water repellant, and once such water repellency has been lost, it is known that water repellency is restored by seeping of low molecular weight siloxanes contained in the silicone rubber to the surface. However, dust or the like readily becomes attached due to viscosity of such low molecular weight siloxanes, and due to water repellency of the low molecular weight siloxanes, once dust has become attached, the dust may be difficult to shed by rain and wind. There is concern that dust attached to the insulator surface may cause lowering of surface resistance, increase of leakage current, localized discharge, and tracking.

### SUMMARY OF THE INVENTION

A product used in outdoor applications, such as an LED advertising display transmissive diffuser panel, a polymer insulator, or the like, preferably has excellent antifouling property. The prevention or suppression of the attachment of dust or the like to the surface by lowering the coefficient of friction of the product surface is cited as one means for the realization of antifouling property.

Thus, an object of the present disclosure is to provide an article including a polymer having a surface that has excellent heat resistance, weathering resistance, or the like and that has a low coefficient of friction, and to provide a manufacturing method for the article.

According to an aspect of the present disclosure, an article is provided that includes a polymer having a surface that has been plasma treated in flowing gas including at least one type of silicon-containing gas selected from the group consisting of tetramethylsilane, hexamethyldisiloxane, and hexamethyldisilazane; the polymer being selected from the group consisting of silicones and fluorocarbon polymers.

According to another aspect of the present disclosure, a manufacturing method is provided for an article having a surface that has a low coefficient of friction; the method comprising a step of plasma treating an article including a polymer selected from the group consisting of silicones and fluorocarbon polymers in a flowing gas including at least one type of silicon-containing gas selected from the group consisting of tetramethylsilane, hexamethyldisiloxane, and hexamethyldisilazane.

### DETAILED DESCRIPTION

According to the aspect of the present disclosure, an article is provided that includes a polymer having a surface that has excellent heat resistance, weathering resistance, or the like and that has a low coefficient of friction. Since this article has a surface that has a low coefficient of friction, antifouling property is excellent, and for example, use is possible with particular advantage for outdoor applications such as an LED-equipped outdoor advertising display, a polymer insulator, or the like. Further, according to another aspect of the present disclosure, it is possible to control optical transmittance and friction characteristics of the plasma treated article by varying electrical power density, composition of the flowing gas, flow rate ratios of the flowing gas, or the like upon plasma treatment.

Note that the description above should not be considered as a complete disclosure of all embodiments of the present invention or of all advantages related to the present invention.

A detailed description for the purpose of illustrating representative embodiments of the present invention is given below, but these embodiments should not be construed as limiting the present invention.

The article of the aspect of the present disclosure includes a polymer having a surface that has been plasma treated in flowing gas including at least one type of silicon-containing gas selected from the group consisting of tetramethylsilane, hexamethyldisiloxane, and hexamethyldisilazane; the polymer being selected from the group consisting of silicones and fluorocarbon polymers. Moreover, the manufacturing method for an article having a surface that has a low coefficient of friction of another aspect of the present disclosure includes a step of plasma treating an article including a polymer selected from the group consisting of silicones and fluorocarbon polymers in a flowing gas including at least one type of silicon-containing gas selected from the group consisting of tetramethylsilane, hexamethyldisiloxane, and hexamethyldisilazane.

The polymer included in the article of the present disclosure defines at least a portion of the surface of the article, and this polymer is generally a solid or a semisolid at room temperature. The polymer may have various shapes such as a film, sheet, rod, fiber, cloth, coating, molded article, or the like. This shape may be that of the article itself or may be a shape incorporated in a portion of the article. The plasma treated article of the present disclosure may be used for an application targeting assembly of the article with other components.

As the polymer selected from the group consisting of silicones and fluorocarbon polymers, it is possible to use polymers of various types of properties, such as thermoplastic resins, thermosetting resins, gels, or the like. Despite the elastomer having a relatively high coefficient of friction due to the viscoelasticity of the elastomer, by plasma treatment of the elastomer in flowing gas including the silicon-containing gas according to the present disclosure, it is possible to remarkably lower the coefficient of friction, and thus it is possible to use with advantage a polymer that is an elastomer in certain embodiments. Any optional component may be added to the polymer, as exemplified by fillers such as silica, carbon, calcium hydroxide, magnesium oxide, or the like, antioxidants, ultraviolet radiation absorption agents, flame retardants, or the like.

Various types of silicones may be used, such as silicone oils, silicone rubbers, silicone gels, or the like, which may be condensation type, addition type, crosslinked type, or similar silicones. A silicone oil, for example, may be used as a curing coating used for at least part of another component. The silicone rubbers and silicone gels may be plasma treated without modification or after curing. After plasma treatment of a non-cured or semi-cured silicone rubber or the like, the silicone rubber or the like may be further cured. The silicone may be selected from among silicones having a hydrogen atom, methyl group, phenyl group, or a combination thereof at the terminal and/or side chain of the polysiloxane chain. It is possible to use a modified silicone that further has a functional group at the silicone terminal and/or side chain, selected from an amino group, epoxy group, alkoxy group, hydroxyl group, mercapto group, carboxyl group, polyether group, aralkyl group, or the like.

Fluorocarbon polymers are exemplified by at least one type of fluorocarbon polymer, copolymer, terpolymer, and materials including crosslinked products of such, and composed mainly of at least one type of fluorinated monomer such as tetrafluoroethylene (TFE), vinyl fluoride, vinylidene fluoride (VDF), hexafluoropropylene (HFP), pentafluoropropylene, trifluoroethylene, chlorotrifluoroethylene (CTFE), perfluoromethyl vinyl ether (PMVE), perfluoropropylvinyl ether (PPVE), or the like. The fluorocarbon polymer may include polymerization units derived from a non-fluorine monomer such as ethylene, propylene, butylene, or the like. In certain embodiments, vinylidene fluoride-tetrafluoroethylene-hexafluoropropylene terpolymer and vinylidene fluoride-hexafluoropropylene copolymer having excellent moldability may be used with advantage as the fluorocarbon polymer.

In certain embodiments, fluoroelastomer copolymers and fluoroelastomer terpolymers may be used with advantage as the fluorocarbon polymer. Such fluoroelastomer copolymers and fluoroelastomer terpolymers are exemplified by vinylidiene fluoride-hexafluoropropylene copolymers, vinylidiene fluoride-tetrafluoroethylene-hexafluoropropylene terpolymers, or the like. Among Dyneon (registered trademark) products produced by 3M Company, as fluoroelastomer polymers, FE 5522X, FE 5730, FE 5830Q, FE 5840Q, FLS 2530, FLS 2650, FPO 3740, FPO 3741, FT 2320, FT 2350, FT 2430, and FT 2481 may be used, and as fluoroelastomer copolymers, FC 2110Q, FC 2120, FC 2121, FC 2122, FC 2123, FC 2144, FC 2145, FC 2152, FC 2170, FC 2174, FC 2176, FC 2177D, FC 2178, FC 2179, FC 2180, FC 2181, FC 2182, FC 2211, FC 2230, FC 2260, FC 2261Q, FE 5520X, FE 5542X, FE 5610, FE 5610Q, FE 5620Q, FE 5621, FE 5622Q, FE 5623, FE 5640Q, FE 5641Q, FE 5642, FE 5643Q, FE 5660Q, FG 5630Q, FG 5661X, FG 5690Q, FX 3734, FX 3735, and FX 11818 may be used.

The plasma treatment of the present disclosure may be performed using a low pressure plasma treatment apparatus equipped with a chamber capable of decompression, or using an atmospheric pressure plasma treatment apparatus. Nitrogen gas and/or a gas of group 18 of the periodic table (such as helium, neon, argon, krypton, xenon, radon, or the like) are used as the discharge gas in atmospheric pressure plasma treatment. Among such gases, nitrogen, helium, and argon are used with advantage, and the use of nitrogen is particularly advantageous from the standpoint of cost. Generally, a low pressure plasma apparatus is used for batch processing. If continuous treatment is needed for an elongated web or the like, the use of an atmospheric pressure plasma treatment apparatus may be advantageous from the standpoint of productivity. A low pressure plasma treatment apparatus is preferably used due to the ability to control the coefficient of friction of the plasma-treated surface of the polymer by maintaining cleanliness of the treated surface of the polymer and by precise control of the plasma. Widely known methods may be used as the form of generation of the plasma, such as corona discharge, dielectric-barrier discharge, single or dual RF discharge (e.g. using a 13.56 MHz high frequency power supply), microwave discharge, arc discharge, or the like. Among such forms of generation, a single RF discharge using a 13.56 MHz high frequency power supply may be used with advantage.

The electrical power to be applied required for generation of the plasma may be determined according to the dimensions of the article to be treated so that, generally, the electrical power density of the discharge space is greater than or equal to approximately 0.05 W/cm², greater than or equal to approximately 0.1 W/cm², or greater than or equal to approximately 0.15 W/cm², and less than or equal to approximately 1.0 W/cm², or less than or equal to approximately 0.3 W/cm². For example, if the article to be plasma treated has 10 cm (length)×10 cm or less (width) dimensions, the electrical power to be applied may be set to greater than or equal to approximately 100 W, greater than or equal to approximately 200 W, or greater than or equal to approximately 400 W, and less than or equal to approximately 2 kW, less than or equal to approximately 1.5 kW, or less than or equal to approximately 1 kW.

The temperature of plasma treatment may be any temperature as long as the characteristics, performance, or the like of the article to be treated are not impaired. For example, surface temperature of the article to be treated may be set to a temperature greater than or equal to approximately −15° C., greater than or equal to approximately 0° C., or greater than or equal to approximately 15° C., and less than or equal to approximately 400° C., less than or equal to approximately 200° C., or less than or equal to approximately 100° C. Surface temperature of the article may be measured by a thermocouple contacting the article, by a radiation thermometer, or the like.

Treatment pressure of plasma treatment using a low pressure plasma treatment apparatus may be set to a pressure greater than or equal to approximately 10 mTorr and less than or equal to approximately 1,500 mTorr.

The silicon-containing gas is selected from the group consisting of tetramethylsilane, hexamethyldisiloxane, and hexamethyldisilazane. Among these silicon-containing gases, tetramethylsilane is used with advantage due to high reactivity and a high diffusion coefficient. Tetramethylsilane, which has a low boiling point, is generally used in an atmospheric pressure plasma treatment apparatus.

The flow rate of silicon-containing gas may be set to greater than or equal to approximately 20 sccm and less than or equal to approximately 500 sccm.

Oxygen may be added to the gas flow supplied to the plasma treatment apparatus. Without any desire to be bound to any theory, the addition of oxygen to the gas flow is thought to cause reaction between the oxygen and the silicon-containing gas, and to increase the deposition efficiency of the silicon-containing gas on the polymer surface. In particular, if the polymer is a silicone, addition of oxygen gas is advantageous in that it is possible to perform treatment under gentle conditions using a low electrical power density. The oxygen may be fed to the chamber of the plasma treatment apparatus using a line separate from that of the silicon-containing gas, or the oxygen gas may be intermixed with the silicon-containing gas and be supplied to a shower head disposed within the chamber. The flow rate of oxygen may be set to greater than or equal to approximately 5 sccm and less than or equal to approximately 500 sccm. The flow ratio of oxygen to the silicon-containing gas, taking the flow rate of the silicon-containing gas to be 1, may be set to approximately 0.1:1 or greater, approximately 0.2:1 or greater, or approximately 0.3:1 or greater, and approximately 5:1 or less, approximately 4:1 or less, or approximately 3:1 or less.

A carrier gas at a flow rate of approximately 50 sccm or greater and approximately 5000 sccm or less such as nitrogen, helium, or argon may be further included in the gas flow. Nitrogen may be incorporated with the plasma-treated surface of the polymer when the nitrogen reacts with the silicon-containing gas to form SiN bonds.

The treatment time of plasma treatment may be set to greater than or equal to approximately 2 seconds, greater than or equal to approximately 5 seconds, or greater than or equal to approximately 10 seconds, and less than or equal to approximately 300 seconds, less than or equal to approximately 180 seconds, or less than or equal to approximately 120 seconds.

Without any desire to be bound to any theory, it is thought that on the polymer surface that has undergone the plasma treatment of the present disclosure, thin films or layers derived from the silicon-containing gas are accumulated, which are formed via Si—CH₂—CH₂—Si bonds, Si—O—Si bonds, Si—N—Si bonds, or the like, and which include a relatively dense network structure. This thin film or layer is thought to have a large amount of Si—CH₃ bonds exposed at the surface, and the thin film or layer is relatively rigid due to the network structure, so that the polymer may have a low friction surface. It is known that the bond dissociation energy of the C—F bond is particularly high. It was thus unexpected that there would be a lowering of coefficient of friction of the fluorocarbon polymer surface by the formation of a thin film or layer derived from silicon-containing gas on a fluorocarbon polymer surface by the plasma treatment of the present disclosure.

Thickness of this thin film or layer may be set by varying the plasma treatment conditions. Generally, such thickness may be set to greater than or equal to approximately 1 nm, greater than or equal to approximately 2 nm, or greater than or equal to approximately 5 nm, and less than or equal to approximately 1 μm, less than or equal to approximately 500 nm, or less than or equal to approximately 10 nm. The expression “thickness of the thin film or layer” in the present disclosure indicates the thickness of the part that has a composition different from the polymer composition and/or is in a bonded state. This part may be determined by cross-sectional observation using a scanning electron microscope, for example. In certain embodiments, the dynamic coefficient of friction of the plasma-treated surface, is greater than or equal to approximately 0.01-fold, greater than or equal to approximately 0.02-fold, or greater than or equal to approximately 0.05-fold, and less than or equal to approximately 0.9-fold, less than or equal to approximately 0.8-fold, or less than or equal to approximately 0.5-fold that of the non-plasma treated surface. The dynamic coefficient of friction may be determined using a friction-abrasion testing machine.

In another embodiment in which the polymer is optically transparent, a total transmittance of the plasma treated article is greater than or equal to approximately 95%, greater than or equal to approximately 96%, or greater than or equal to approximately 97% total transmittance of the non-plasma treated article. The total transmittance may be determined by a haze meter. Further, in another embodiment, the haze value of the plasma-treated article is less than or equal to approximately 3-fold, less than or equal to approximately 2.5-fold, or less than or equal to approximately 2-fold that of the non-plasma treated article. The total transmittance and the haze value may be measured in accordance with JIS K 7136 (2000) and JIS K 7361-1 (1997). The haze value may be determined as equal to (diffuse transmittance/total transmittance)×100. Without being restricted to any theory, when the polymer is a silicone, and when the electrical power density is increased and the flow rate of the silicon-containing gas is increased, the difference between the composition of the plasma-treated surface and the polymer composition (i.e. the difference in refractive index between the plasma-treated surface and the polymer) increases, and there is a tendency for whitening to occur. Thus, in applications where the polymer is silicone and a low haze value is required, the flow rate of silicon-containing gas is preferably set to greater than or equal to approximately 50 sccm and less than or equal to approximately 500 sccm, and the electrical power density is preferably set to greater than or equal to approximately 0.05 W/cm² and less than or equal to approximately 1.0 W/cm².

In another embodiment, a contact angle of water with the surface of the plasma-treated article is greater than or equal to approximately 90°, greater than or equal to approximately 95°, or greater than or equal to approximately 100°. The contact angle may be determined using a contact angle meter, by the sessile drop method, by using a liquid droplet volume of 4 μL, measuring contact angle 5 times, and then determining the contact angle as the average of the measured values.

Since the article of the present disclosure has a surface that has a low coefficient of friction, the antifouling property is excellent, and it is possible to use the article of the present disclosure with advantage particularly for outdoor applications such as an LED-equipped outdoor advertising display, polymer insulator, or the like.

Various embodiments are provided that are articles or methods of manufacturing the article.

Embodiment 1 is an article comprising a polymer having a surface that has been plasma treated in flowing gas including at least one type of silicon-containing gas selected from the group consisting of tetramethylsilane, hexamethyldisiloxane, and hexamethyldisilazane, the polymer being selected from the group consisting of silicones and fluorocarbon polymers.

Embodiment 2 is the article of embodiment 1, wherein the silicon-containing gas is tetramethylsilane.

Embodiment 3 is the article of embodiment 1 or 2, wherein a dynamic coefficient of friction of the plasma-treated surface is from 0.01 to 0.9 times that of the non-plasma treated surface.

Embodiment 4 is the article of any one of embodiments 1 to 3, wherein the polymer is an elastomer.

Embodiment 5 is the article of any one of embodiments 1 to 4, wherein the flowing gas further includes oxygen.

Embodiment 6 is the article of embodiment 5, wherein a ratio of flow rates of oxygen to the silicon-containing gas in the flowing gas is from 0.1:1 to 5:1.

Embodiment 7 is the article of any one of embodiments 1 to 6, wherein the polymer is a silicone.

Embodiment 8 is the article of any one of embodiments 1 to 6, wherein the polymer is a fluorocarbon polymer.

Embodiment 9 is a manufacturing method for an article having a surface with a low coefficient of friction, the method comprising a step of plasma treating an article comprising a polymer selected from the group consisting of silicones and fluorocarbon polymers in a flowing gas including at least one type of silicon-containing gas selected from the group consisting of tetramethylsilane, hexamethyldisiloxane, and hexamethyldisilazane.

Embodiment 10 is the method of embodiment 9, wherein the silicon-containing gas is tetramethylsilane.

Embodiment 11 is the method of embodiment 9 or 10, wherein the polymer is an elastomer.

Embodiment 12 is the method of any one of embodiments 9 to 11, wherein the flowing gas further includes oxygen.

Embodiment 13 is the method of any one of embodiments 9 to 12, wherein a ratio of flow rates of oxygen to the silicon-containing gas in the flowing gas is from 0.1:1 to 5:1.

Embodiment 14 is the method of any one of embodiments 9 to 13, wherein an electrical power density of a discharge space in the plasma treatment is from 0.05 to 1.0 W/cm².

Embodiment 15 is the method of any one of embodiments 9 to 14, wherein a time of plasma treatment is from 2 to 300 seconds.

### EXAMPLES

In the following examples, specific embodiments of the present disclosure are exemplified, but the present invention is not restricted thereto. All parts and percentages are by mass unless otherwise indicated.

In the present examples, a silicone elastomer (ELSTOSIL RT 601, Wacker Asahikasei Silicone Co., Ltd.) and a fluoroelastomer composition having the composition of Table 1 were used as materials that constitute an article to be subjected to plasma treatment.

TABLE 1

| Trade name | Description | Parts by |
|---|---|---|
| FC-2179 | Vinylidiene fluoride/hexafluoropropylene | 100 |
| | copolymer, 3M Company | |
| MT-carbon | Degussa-Huels/N990 | 5 |
| Cal-em | Ca(OH)₂, Ohmi Chemical Industry Co., Ltd. | 6 |
| Magnesium | #150, Kyowa Chemical Industry Co., Ltd. | 3 |
| hydroxide | | |

### Comparative Example 1

27.0 of liquid A and 3.0 g of liquid B of RT 601 (i.e. two-liquid curing type silicone elastomer) were placed in a glass vessel placed within a centrifugal stirring device. Agitation and degassing treatment were performed, each for 2 minutes. Thereafter, the obtained viscous mixture was poured into a mold constituted by stainless steel spacers and a glass plate (bottom plate) for forming a sheet of 100 mm×100 mm×2 mm size. The mold containing the mixture was placed in a vacuum box constructed from acrylic resin, and deaeration was performed for 6 minutes at 0.1 MPa. The sample in the mold was cured for 24 h at room temperature. The 2 mm thick silicone sheet obtained in this manner was cut to obtain a sample of 30 mm×30 mm×2 mm size.

### Examples 1 to 15 and Comparative Examples 2 to 4

The silicone sheet obtained in Comparative Example 1 was subjected to plasma treatment for 60 seconds at 25° C. temperature, at a pressure of 100 mTorr, and at an electrical power density of 0.068 W/cm² (200 W applied electrical power), 0.171 W/cm² (500 W applied electrical power), or 0.274 W/cm² (800 W applied electrical power) in the presence of tetramethylsilane (TMS) and/or oxygen, using a plasma treatment apparatus WB 7000 (Plasma-Therm Industrial Products, Inc.). Plasma treatment conditions are shown in Table 2.

### Comparative Example 5

The aforementioned fluoroelastomer composition was placed in a mold constituted by stainless-copper spacers and 2 sheets of stainless steel plate for forming a sheet of 100 mm×100 mm×2 mm size. After pressing stainless steel plates of the mold from above and bottom at a pressure of 0.83 MPa at 170° C. for 10 minutes, the mold was placed in an oven at 230° C. for 24 h. The 2 mm thick fluoroelastomer sheet obtained in this manner was cut to obtain a sample of 30 mm×30 mm×2 mm size.

### Examples 16 to 27 and Comparative Example 6

In the same manner as Examples 1 to 15 and Comparative Examples 2 to 4, the fluoroelastomer sheet obtained in Comparative Example 5 was subjected to plasma treatment. Plasma treatment conditions are shown in Table 3.

### Evaluation Methods

The characteristics of the sheets of Examples 1 to 27 and Comparative Examples 1 to 6 were evaluated according to the following methods.

### Optical Characteristics

The total transmittance, haze value, diffuse transmittance, and parallel transmittance were measured in accordance with JIS K 7136 (2000) and JIS K 7361-1 (1997) using a haze meter NDH-5000 W (obtained from Nippon Denshoku Industries Co., Ltd.). The haze value was calculated by the following formula.

Haze value=(diffuse transmittance/total transmittance)×100

### Friction Characteristics

The frictional force was measured in accordance with JIS T-0303 using a Friction Player FPR-2100 (obtained from RHESCA Co., Ltd.) and a 3×3 cm² fixed sample piece by 30 reciprocations at 25° C. at 14.5 mm/second velocity, 50 g (0.49 N) load, and 14.5 mm stroke length. The absolute values of the measured values were averaged and taken to be the frictional force. The dynamic coefficient of friction was calculated by dividing the frictional force by the load of 0.49 N.

### Contact Angle

The water contact angle of the sheet surface was measured by the Sessile Drop method using a contact angle meter (obtained from Kyowa Interface Science Co., Ltd. under the product name “DROPMASTER FACE”). The volume of liquid droplets was set to 4 μL, for static measurements. The value of the water contact angle was calculated from the average of five measurements.

The evaluation results of the silicone sheets of Examples 1 to 15 and Comparative Examples 1 to 4 are shown in Table 2

TABLE 2

| | | Plasma treatment conditions | | | | | Friction | | Optical Properties | | | |
|---|---|---|---|---|---|---|---|---|---|---|---|---|
| | | | | | Electrical | | characteristics | | Total | | Diffuse | Parallel |
| | | | | Applied | power | | Frictional | Dynamic | transmit- | | transmit- | transmit- |
| | Treatment | Pressure | Flow rate | electrical | density | Time | force | coefficient | tance | Haze | tance | tance |
| | gas | [mTorr] | [sccm] | power [W] | [W/cm²] | [seconds] | [N] | of friction | [%] | value | [%] | [%] |
| Comparative | | | | | | | 2.81 | 5.73 | 94.3 | 9.00 | 8.5 | 85.8 |
| Example 1 | | | | | | | | | | | | |
| Comparative | O₂ | 100 | 200 | 200 | 0.068 | 60 | 2.75 | 5.61 | 93.4 | 9.27 | 8.7 | 84.8 |
| Example 2 | | | | | | | | | | | | |
| Example 1 | TMS/O₂ | 100 | 40/160 | 200 | 0.068 | 60 | 1.76 | 3.59 | 93.3 | 9.14 | 7.0 | 84.8 |
| Example 2 | TMS/O₂ | 100 | 80/120 | 200 | 0.068 | 60 | 2.06 | 4.20 | 93.0 | 9.53 | 8.9 | 84.2 |
| Example 3 | TMS/O₂ | 100 | 120/80 | 200 | 0.068 | 60 | 1.60 | 3.27 | 93.3 | 9.03 | 8.4 | 84.9 |
| Example 4 | TMS/O₂ | 100 | 160/40 | 200 | 0.068 | 60 | 2.32 | 4.73 | 93.5 | 8.72 | 8.2 | 85.4 |
| Example 5 | TMS | 100 | 200 | 200 | 0.068 | 60 | 2.91 | 5.94 | 93.3 | 8.05 | 7.5 | 85.8 |
| Comparative | O₂ | 100 | 200 | 500 | 0.171 | 60 | 2.66 | 5.43 | 93.6 | 9.22 | 8.6 | 85.0 |
| Example 3 | | | | | | | | | | | | |
| Example 6 | TMS/O₂ | 100 | 40/160 | 500 | 0.171 | 60 | 0.56 | 1.14 | 92.7 | 11.48 | 10.6 | 82.0 |
| Example 7 | TMS/O₂ | 100 | 80/120 | 500 | 0.171 | 60 | 0.82 | 1.67 | 93.2 | 11.20 | 10.4 | 82.7 |
| Example 8 | TMS/O₂ | 100 | 120/80 | 500 | 0.171 | 60 | 0.76 | 1.55 | 93.0 | 12.19 | 11.3 | 81.7 |
| Example 9 | TMS/O₂ | 100 | 160/40 | 500 | 0.171 | 60 | 0.29 | 0.59 | 93.6 | 14.81 | 12.9 | 79.8 |
| Example 10 | TMS | 100 | 200 | 500 | 0.171 | 60 | 0.34 | 0.69 | 92.6 | 15.73 | 14.6 | 85.8 |
| Comparative | O₂ | 100 | 200 | 800 | 0.274 | 60 | 2.61 | 5.33 | 93.7 | 8.75 | 8.2 | 85.5 |
| Example 4 | | | | | | | | | | | | |
| Example 11 | TMS/O₂ | 100 | 40/160 | 800 | 0.274 | 60 | 0.18 | 0.37 | 93.3 | 33.77 | 31.5 | 61.8 |
| Example 12 | TMS/O₂ | 100 | 80/120 | 800 | 0.274 | 60 | 0.16 | 0.33 | 93.2 | 39.59 | 36.9 | 56.3 |
| Example 13 | TMS/O₂ | 100 | 120/80 | 800 | 0.274 | 60 | 0.15 | 0.31 | 93.1 | 43.73 | 40.7 | 52.4 |
| Example 14 | TMS/O₂ | 100 | 160/40 | 800 | 0.274 | 60 | 0.13 | 0.27 | 92.5 | 49.14 | 45.5 | 47.1 |
| Example 15 | TMS | 100 | 200 | 800 | 0.274 | 60 | 0.12 | 0.24 | 90.5 | 72.45 | 65.6 | 24.9 |

The evaluation results of the fluoroelastomer sheets of Examples 16 to 27 and Comparative Examples 5 to 6 are shown in Table 3.

TABLE 3

| | | Plasma treatment conditions | | | | | Friction | | |
|---|---|---|---|---|---|---|---|---|---|
| | | | | | Electrical | | characteristics | | Contact |
| | | | | Applied | power | | Frictional | Dynamic | Angle |
| | | Pressure | Flow rate | electrical | density | Time | force | coefficient | H₂O |
| | Treatment gas | [mTorr] | [sccm] | power [W] | [W/cm²] | [seconds] | [N] | of friction | [°] |
| Comparative | | | | | | | 1.95 | 3.98 | 102.6 |
| Example 5 | | | | | | | | | |
| Comparative | O₂ | 50 | 200 | 500 | 0.171 | 60 | 1.90 | 3.88 | 89.3 |
| Example 6 | | | | | | | | | |
| Example 16 | TMS/O₂ | 50 | 40/160 | 500 | 0.171 | 60 | 0.13 | 0.27 | 81.2 |
| Example 17 | TMS/O₂ | 48 | 80/120 | 500 | 0.171 | 60 | 0.12 | 0.24 | 95.9 |
| Example 18 | TMS/O₂ | 44 | 120/80 | 500 | 0.171 | 60 | 0.11 | 0.22 | 100.6 |
| Example 19 | TMS/O₂ | 43 | 160/40 | 500 | 0.171 | 60 | 0.13 | 0.27 | 104.0 |
| Example 20 | TMS/O₂ | 43 | 182/18 | 500 | 0.171 | 60 | 0.12 | 0.24 | 105.9 |
| Example 21 | TMS | 43 | 200 | 500 | 0.171 | 60 | 0.14 | 0.29 | 112.3 |
| Example 22 | TMS/O₂ | 43 | 40/160 | 200 | 0.068 | 60 | 0.16 | 0.33 | 90.9 |
| Example 23 | TMS/O₂ | 43 | 80/120 | 200 | 0.068 | 60 | 0.16 | 0.33 | 97.6 |
| Example 24 | TMS/O₂ | 40 | 120/80 | 200 | 0.068 | 60 | 0.14 | 0.29 | 100.2 |
| Example 25 | TMS/O₂ | 43 | 160/40 | 200 | 0.068 | 60 | 0.24 | 0.49 | 108.0 |
| Example 26 | TMS/O₂ | 43 | 182/18 | 200 | 0.068 | 60 | 0.16 | 0.33 | 103.2 |
| Example 27 | TMS | 43 | 200 | 200 | 0.068 | 60 | 0.15 | 0.31 | 104.0 |

1. An article comprising a polymer having a plasma-treated surface that has been plasma treated in flowing gas including at least one type of silicon-containing gas selected from the group consisting of tetramethylsilane, hexamethyldisiloxane, and hexamethyldisilazane, the polymer being selected from the group consisting of silicones and fluorocarbon polymers, wherein a dynamic coefficient of friction of the plasma-treated surface is 0.01 to 0.9 times that of a non-plasma treated surface of the polymer.

2. The article of claim 1, wherein the silicon-containing gas is tetramethylsilane.

3. (canceled)

4. The article of claim 1, wherein the polymer is an elastomer.

5. The article of claim 1, wherein the flowing gas further includes oxygen.

6. The article of claim 5, wherein a ratio of flow rates of oxygen to the silicon-containing gas in the flowing gas is from 0.1:1 to 5:1.

7. The article of claim 1, wherein the polymer is a silicone.

8. The article of claim 1, wherein the polymer is a fluorocarbon polymer.

9. A manufacturing method for an article having a surface with a low coefficient of friction, the method comprising:
providing an article comprising a polymer having a surface, the polymer selected from a silicone or fluorocarbon polymer;
plasma treating the surface of the polymer in a flowing gas comprising at least one type of silicon-containing gas selected from the group consisting of tetramethylsilane, hexamethyldisiloxane, and hexamethyldisilazane to form a plasma-treated surface, wherein a dynamic coefficient of friction of the plasma-treated surface is 0.01 to 0.9 times that of a non-plasma treated surface of the polymer.

10. The method of claim 9, wherein the silicon-containing gas is tetramethylsilane.

11. The method of claim 9, wherein the polymer is an elastomer.

12. The method of claim 1, wherein the flowing gas further includes oxygen.

13. The method of claim 12, wherein a ratio of flow rates of oxygen to the silicon-containing gas in the flowing gas is from 0.1:1 to 5:1.

14. The method of claim 9, wherein an electrical power density of a discharge space in the plasma treatment is from 0.05 to 1.0 W/cm².

15. The method of claim 9, wherein a time of plasma treatment is from 2 to 300 seconds.
